(19) United States
(12) Patent Application Publication
(10) Pub. No.: US 2023/0250927 A1
(43) Pub. Date: Aug. 10, 2023

(54) FLEXIBLE LIGHT EMITTING DIODE (LED) SHEET SYSTEMS AND METHODS

(71) Applicant: Diodify, LLC, Frisco, TX (US)

(72) Inventors: James Boros, Colleyville, TX (US); Kelly Blackwood Carter, Colleyville, TX (US)

(73) Assignee: Diodify, LLC, Frisco, TX (US)

(21) Appl. No.: 18/099,476

(22) Filed: Jan. 20, 2023

Related U.S. Application Data
(63) Continuation-in-part of application No. 17/989,469, filed on Nov. 17, 2022.
(60) Provisional application No. 63/280,584, filed on Nov. 17, 2021.

(51) Int. Cl. F21S 4/26; H01L 25/075; H01L 33/62; F21V 23/06

(52) U.S. Cl. CPC F21S 4/26; H01L 25/0753; H01L 33/62; F21V 23/06; F21Y 2115/10

(57) ABSTRACT

A flexible light emitting diode (LED) sheet operable to (i) produce light, (ii) enhance an amount of light and/or connected light-emitting diodes and/or sheets that can be daisy chained together, and (iii) lower wattage consumption. Lighting options include single color, color changing lighting, and pixel lighting. Some examples include one or more strips of LEDs (e.g., in a 12 volt configuration) adhered to one or more substrate surfaces. The one or more substrate surfaces can include one or more posts that extend through openings of an inner frame, such that the substrate surface(s) and inner frame couple together to form a backlighting frame. Additionally or alternatively, the one or more substrate surfaces can be arranged at 90 degree angles and/or in a plurality of parallel lines to form an LED array, one or more LED panels, and/or a three-dimensional illumination object (e.g., a rectangular prism).

### CROSS-REFERENCE TO RELATED APPLICATIONS

This application is a continuation-in-part of and claims priority to U.S. patent application Ser. No. 17/989,469, filed Nov. 17, 2022 and titled “FLEXIBLE LIGHT EMITTING DIODE (LED) SHEET SYSTEMS AND METHODS;” which claims priority to U.S. Provisional Patent Application No. 63/280,584, titled “FLEXIBLE LED SHEET OF LIGHT SYSTEMS AND METHODS” and filed Nov. 17, 2021, the entireties of which are incorporated herein by reference.

### BACKGROUND

Signage, art, decorations, safety lighting, decor lighting, and many other products make use of different forms of illumination. However, creating a specialized illumination element to match the shapes of these products can be difficult due to the need to create unique lighting arrangements, manage wires, and maintain connectivity and power while modifying the lighting circuitry. These difficulties can be compounded for complex three-dimensional objects with large intricate interior and exterior surfaces that may require lighting. Large scale customized light fixtures with complex wire configurations require significant time to construct and substantial power to operate.

It is with these observations in mind, among others, that various aspects of the presently disclosed technology were conceived and developed.

### BRIEF SUMMARY

The aforementioned issues can be addressed using the technology disclosed herein. For instance a lighting system can include a strip of light emitting diodes (LED)s operable to produce light, the strip of LEDs including a plurality of power connection points; a substrate surface to which the strip of LEDS are attached; and/or a wire connecting the strip of LEDs to a power supply at an interior power connection point of the plurality of power connection points which is inset from an end power connection point of the plurality of power connection points. The lighting system can further include an SK6812 IC chip with one or more resistors creating a 12 volt configuration for the strip of LEDs. Moreover, in some scenarios, the strip of LEDS is a first strip of LEDs, the wire is a first wire, and the interior power connection point is a first interior power connection point; and/or the lighting system further includes a second strip of LED attached to the substrate surface and electrically coupled to the first strip of LEDs with a second wire connecting to a second interior power connection point on the second strip of LEDS. Furthermore, the second strip of LEDs can be arranged perpendicularly to the first strip of LEDs.

In some instances, the second strip of LEDs is arranged parallel to the first strip of LEDS. The first wire or the second wire can extend through the substrate surface from behind the substrate surface. Also, the first wire or the second wire can be adhered to the substrate surface with a glue or tape. The substrate surface can form an elongated bracket coupled to an interior frame to form a backlighting frame. Furthermore, the strip of LEDs can be one of a plurality of strips of LEDs arranged in parallel rows having a same length on the substrate surface to form an LED panel having a uniform illumination pattern. Additionally or alternatively, the LED panel is one of a plurality of LED panels arranged perpendicularly to form an LED cube or an LED rectangular prism.

In some examples, a lighting system includes a strip of LEDs operable to produce light, the strip of LEDs including an interior power connection point inset from an end power connection point, the interior power connection point is coupled to a power supply; a substrate surface to which the strip of LEDS are attached forming an elongated bracket; and/or an interior frame having one or more openings receiving one or more mounting bolts, extending from the elongated bracket, such that the elongated bracket couples to the interior frame to form a backlighting frame. Furthermore, the elongated bracket can be one of a plurality of elongated brackets, having a plurality of substrate surfaces coupled together to form a rectangle with the plurality of substrate surfaces facing towards an interior of the rectangle; and/or the lighting system can further include a plurality of strips of LEDs coupled to the plurality of elongated brackets to form a continuous illumination pattern around the rectangle. Additionally or alternatively, the lighting system can further include a plurality of channels formed into the plurality of substrate surfaces for receiving the plurality of strips of LEDs; and/or a fabric stretched across a perimeter edge defined by the plurality of elongated brackets, the fabric receiving backlighting from the plurality of strips of LEDs.

In some examples, the perimeter edge defined by the plurality of elongated brackets is spaced a distance apart from the plurality of strips of LEDs such that an illumination pattern from the plurality of strips of LEDs reaching the perimeter edge causes the backlighting of the fabric to omit edge shadows. Moreover, the elongated bracket can be a double-sided bracket with the perimeter edge being a front perimeter edge; and/or the lighting system can further include a rear perimeter edge defined by the plurality of elongated brackets, such that the one or more mounting bolts extend from a center portion of the elongated bracket spaced between the front perimeter edge and a rear perimeter edge. Additionally, the interior frame can be a first interior rectangular frame; and/or the backlighting frame can include a second interior rectangular frame arranged adjacent to the first interior rectangular frame. Also, the elongated bracket can be one of a plurality of elongated brackets including a first top bracket extending along a first top portion of the first interior rectangular frame; and/or a second top bracket, arranged end-to-end with the first top bracket, extending along a second top portion of the second interior rectangular frame.

In some examples, a method of forming a lighting system includes attaching a strip of LEDs, operable to produce light, to a substrate surface, the strip of LEDs including one or more interior power connection points and one or more end power connection points; and/or electrically coupling a wire to at least one of the one or more interior power connection points to provide power to the strip of LEDS such that an illumination pattern of the strip of LEDS omits wire shadows or perimeter edge shadows. Additionally or alternatively, the strip of LEDs is one of a plurality of strips of LEDs coupled to one or more substrate surfaces; and/or the method further includes coupling the one or more substrate surfaces to a base structure to form an illumination structure. For instance, the base structure can include a plurality of panels, and the illumination structure can be a rectangular prism or cube formed by the plurality of panels; and/or the base structure can include one more interior frames with openings for receiving a plurality of bolts extending from the one or more substrate surfaces.

The foregoing summary is intended to be illustrative and is not meant in a limiting sense. Many features of the examples may be employed with or without reference to other features of any of the examples. Additional aspects, advantages, and/or utilities of the presently disclosed technology will be set forth in part in the description that follows and, in part, will be apparent from the description, or may be learned by practice of the presently disclosed technology.

### BRIEF DESCRIPTION OF THE DRAWINGS

The foregoing summary, as well as the following detailed description, will be better understood when read in conjunction with the appended drawings. For the purpose of illustration, there is shown in the drawings certain examples of the disclosed subject matter. It should be understood, however, that the disclosed subject matter is not limited to the precise examples and features shown. The accompanying drawings, which are incorporated in and constitute a part of this specification, illustrate implementations of systems, methods, and devices consistent with the disclosed subject matter and, together with the description, serves to explain advantages and principles consistent with the disclosed subject matter, in which:

FIG. 1 illustrates an example system including a flexible light emitting diode (LED) sheet;

FIG. 2 illustrates an example system including a single color flexible LED sheet;

FIG. 3 illustrates an example system including a multi-color flexible LED sheet;

FIGS. 4A and 4B illustrate an example system including a pixel LED sheet; and

FIG. 5 illustrates an example system including a flexible LED sheet with a power supply and/or a controller;

FIG. 6 illustrates an example method the can be performed with the systems depicted in FIGS. 1-5;

FIG. 7 illustrates an example system including an illumination frame formed with one or more strips of LEDS attached to one or more elongated brackets;

FIG. 8 illustrates an example system including an illumination frame using double-sided elongated brackets attached to an inner frame;

FIG. 9 illustrates an example system including an illumination frame using single-sided elongated brackets attached to an inner frame;

FIG. 10 illustrates an example system including an illumination frame using two inner frames with elongated brackets arranged end-to-end;

FIG. 11 illustrates an example system including an illumination frame using a single-sided elongated brackets with a SEG fabric;

FIG. 12 illustrates an example system including a strip of LEDs with a 12 volt configuration;

FIG. 13 illustrates example systems including a first LED strip electrically coupled to a second LED strip;

FIG. 14 illustrates example systems including an LED strip with a translucent cover; and

FIG. 15 illustrates an example system including a plurality of LED panels forming a three-dimensional LED object.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the examples described herein. However, it will be understood by those of ordinary skill in the art that the examples described herein can be practiced without these specific details. In other instances, methods, procedures and components have not been described in detail so as not to obscure the related relevant feature being described. Also, the description is not to be considered as limiting the scope of the examples described herein. The drawings are not necessarily to scale and the proportions of certain parts may be exaggerated to better illustrate details and features of the present disclosure.

### I. Terminology

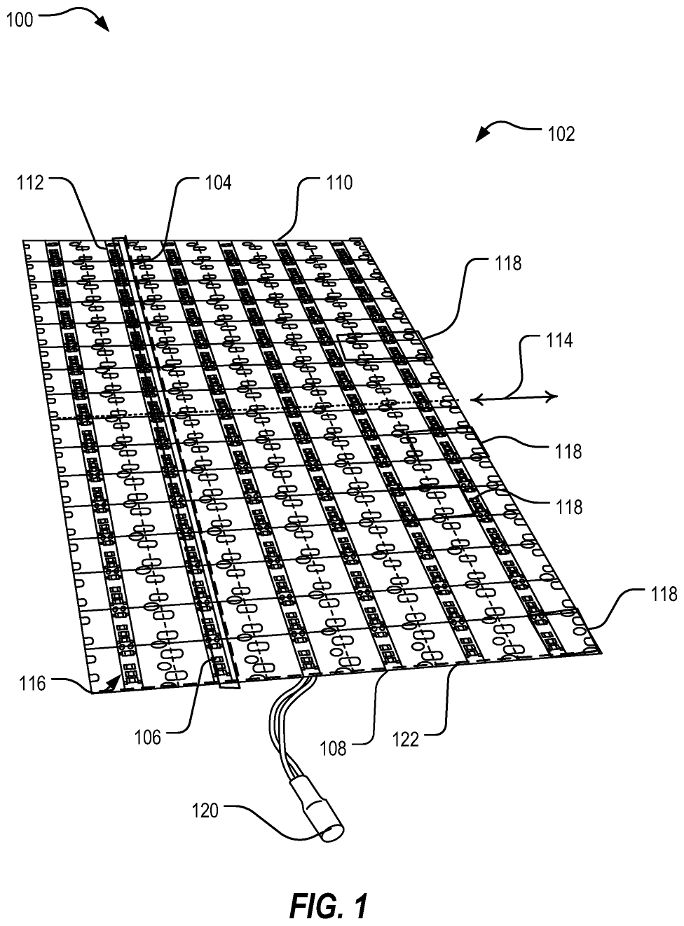

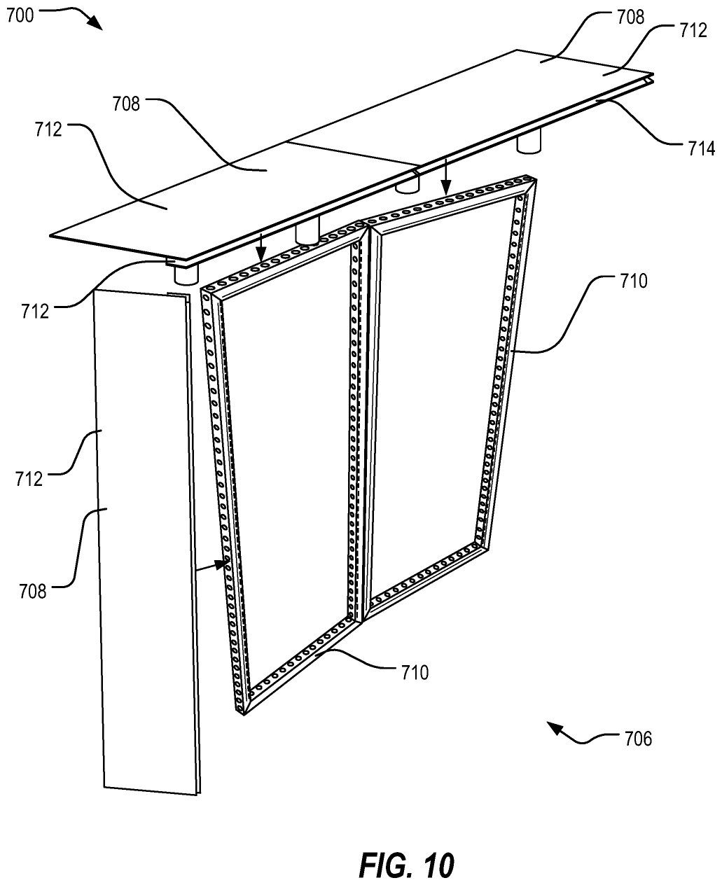

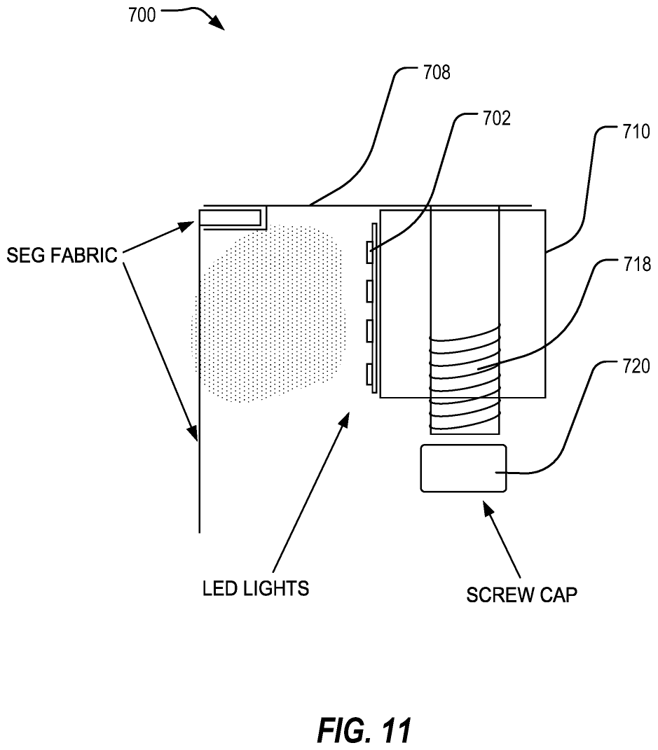

The phraseology and terminology employed herein are for the purpose of description and should not be regarded as limiting. For example, the use of a singular term, such as, “a” is not intended as limiting of the number of items. Further, it should be understood that any one of the features of the presently disclosed technology, as depicted in FIGS. 1-15, may be used separately or in combination with any other disclosed features (e.g., any other features of FIGS. 1-15). Other systems, methods, features, and advantages of the presently disclosed technology will be, or become, apparent to one with skill in the art upon examination of the figures and the detailed description. It is intended that all such additional systems, methods, features, and advantages be included within this description, be within the scope of the presently disclosed technology, and be protected by the accompanying claims.

Further, as the presently disclosed technology is susceptible to examples of many different forms, it is intended that the present disclosure be considered as an example of the principles of the presently disclosed technology and not intended to limit the presently disclosed technology to the specific arrangements shown and described. Any one of the features of the presently disclosed technology may be used separately or in combination with any other feature. References to the terms “instances,” “scenarios,” “examples,” and/or the like in the description mean that the feature and/or features being referred to are included in, at least, one aspect of the description. Separate references to these terms and/or the like in the description do not necessarily refer to the same example and are also not mutually exclusive unless so stated and/or except as will be readily apparent to those skilled in the art from the description. For example, a feature, structure, process, step, action, or the like described in one example may also be included in other examples, but is not necessarily included. Thus, the presently disclosed technology may include a variety of combinations and/or integrations of the examples described herein. Additionally, all aspects of the present disclosure, as described herein, are not essential for its practice. Likewise, other systems, methods, features, and advantages of the presently disclosed technology will be, or become, apparent to one with skill in the art upon examination of the figures and the description. It is intended that all such additional systems, methods, features, and advantages be included within this description, be within the scope of the presently disclosed technology, and be encompassed by the claims.

Any term of degree such as, but not limited to, “substantially,” as used in the description and the appended claims, should be understood to include an exact, or a similar, but not exact configuration. The terms “comprising,” “including” and “having” are used interchangeably in this disclosure. The terms “comprising,” “including” and “having” mean to include, but not necessarily be limited to the things so described.

Lastly, the terms “or” and “and/or,” as used herein, are to be interpreted as inclusive or meaning any one or any combination. Therefore, “A, B, or C” or “A, B, and/or C” mean any of the following: “A,” “B,” or “C”; “A and B”; “A and C”; “B and C”; “A, B and C.” An exception to this definition will occur only when a combination of elements, functions, steps or acts are in some way inherently mutually exclusive.

### II. General Architecture

Systems, methods, and devices disclosed herein can address the aforementioned issues with an improved flexible LED sheets that can accommodate quality LED chips, higher quality PCB circuits, and higher a quality pattern of lighting. The flexible LED sheet disclosed herein is more easily customized, can efficiently connect together with more additional sheets without requiring higher wattages, e.g., via a daisy chain, and can accommodate one or more screws through the sheets. The systems can provide a flexible LED Lighting sheet with a unique patten of lighting to maximize the total number of LEDs that can be daisy chained in a series. This flexible LED light sheet that can be cut horizontal and/or vertically. The sheet can have multiple locations with markings to allow the use of a screw to penetrate one or more printed circuit boards (PCBs) located on the flexible LED light sheet to safely secure it to a surface (e.g., of an object being illuminated by the sheet).

The flexible LED light sheet can include multiple different PCB circuit designs, such as a single color LED arrangement, a multi-color/color changing LED arrangement, a single pixel color LED arrangement. and/or a color changing pixel LED arrangement. Furthermore, in any arrangement, the flexible LED light sheet can be operable for use with 12 V and can be manipulated/reconfigured for use with 5V or 24V. The technology disclosed herein can be used to backlight such material as acrylic and fabrics, for example, forming a sign. The technology can backlight any object while maximizing light output, light quantity, and can use a reduction in wattage.

As such, the technology disclosed herein can provide improved LED spacing and patterns that have a higher quantity of LED that can be in a continuous daisy chain with a total amount of LEDs able to connect to one point of power or one power source. The LEDs can be of a higher quality with the 200 watt power provided. Furthermore, the presently disclosed technology can advantageously consumers less power than previous systems, can advantageously function using a single point of contact for double the amount of size, can advantageously back light more surface area with less material and power consumption, and advantageously provide more options to mount the product via defined PCB locations to guide screws, when mounting, that easily penetrate through the PCB sheet without damaging any sensitive components such as any LEDs, wiring, switches, and the like, and/or can provide for easier and faster installation, and is operable to back light more surface area.

In some examples, the presently disclosed technology includes pixels secured to a flexible, cuttable sheet, and can have a unique scale/unique dimensions not available via any previous systems, which may be limited to small scales or are unable to be provided via larger scales given. For example, the flexible sheet can be a larger sheet with thousands of controllable LEDS without requiring additional connectors and/or breaking the sheet into multiple sheets. As such, the presently disclosed technology advantageously provides maximum capacity and, therefore, advantageously enables lighting control developers to increase capacity of control systems to control more LEDs using less resources and increase control and software capabilities. The presently disclosed technology can advantageously provide a higher lighting capacity using a continual daisy chained lighting system from a single connector. Furthermore, the presently disclosed technology can be manufactured using less material, and may be manufactured, assembled, cut to a customized shape, and/or operated easily without specialized skill. As such, the assemblies including tis technology can be assembled/installed faster with increased flexibility/adaptability. The end result products and/or illuminated objects can be illuminated while consuming less power, and with unique patterns and/or designs to accommodate an increased number of possible applications by an end user.

The presently disclosed technology may be utilized in various applications, such as backlighting acrylic and/or fabric, at tradeshows or exhibits, as part of an art installation, as informational signage, as interior lighting, as exterior lighting, and so forth. Furthermore, various illumination backlight framing and/or illumination objects can be formed in a highly efficient and customizable manufacturing process using the techniques disclosed herein. These illumination structures can form an illumination portion or layer of the signage or installation with the benefit of easier installation, customizability during and after installation, and a simplified take down processes. As such, these techniques provide additional adaptability for creating the illumination frame, surface, or object on-location.

In some examples, the LEDS can form an LED array having a spacing of approximately 1.5″ between the LEDS (e.g., in a horizontal direction and a vertical direction). For instance, the LEDs can form a plurality of 1.5″×1.5″ squares. With this configuration, the LEDs can provide optimal backlighting (e.g., for acrylics or fabrics) when coupled to the object being illuminated with a 3″ spacing between the LED and the surface being illuminated. Furthermore, a plurality of LED sheets can be daisy chained together to form very large LED sheets and displays, (e.g., overcoming PCB machine manufacturing limitations). The LED sheets can be daisy chained together using a single wire lead connecting the ends of the LED sheets together, or the LED sheets may have connectors embedded in the LED strips for directly coupling together.

Additional advantages and benefits of the presently disclosed technology will become apparent from the detailed description below.

Turning to FIG. 1, a lighting system 100 can include a flexible LED sheet 102. The flexible LED sheet 102 can be formed of a flexible material, such as a flexible printed circuit board (PCB). The flexible LED sheet 102 can be operable to produce light, for instance, using a plurality of conductive rows 104 that connect a plurality of LEDs 106. For instance, the conductive row(s) 104 can be parallel to each other and can extend from a first end 108 of the flexible LED sheet 102 to a second end 110 of the flexible LED sheet 102. Each conductive rows 104 can provide power to the row of LEDs 112 on that particular conductive row 104. In some instances, the conductive rows 104 can be a conductive material (e.g., a metal lead) embedded in the flexible PCB material of the flexible LED sheet 102. The conductive rows 104 can correspond to rows of LEDs 112. The LEDs from the different rows of LEDs 112 can align in a lateral direction 114 (e.g., a direction perpendicular to the conductive rows 104, such that the LEDs form an LED array 116 or LED grid. In some scenarios, the flexible LED sheet 102 includes a power connector 120 disposed at an edge of the flexible LED sheet 102 (e.g., at the 108). The power connector 120 can connect to a power source and, using the conductive rows 104 as well as one or more conductive paths 122 traversing and/or connecting the conductive rows 104, provide power to the rows of LEDs 112. Furthermore, the flexible LED sheet 102 can include a plurality of power connectors 120 at the first end 108 and at the second end 112, such that the conductive rows 104 of one flexible LED sheet 102 can be connected, end-to-end, with one or more additional flexible LED sheets 102 using a daisy chain arrangement. In this way, the flexible LED sheet 102 can be expanded in size and lighting capacity. Additionally, portions of the flexible LED sheet 102 can be designated to be cut and/or punctured such that the flexible LED sheet 102 can be changed or reduced in size, such that the flexible LED sheet 102 can be fully customized in shape and size.

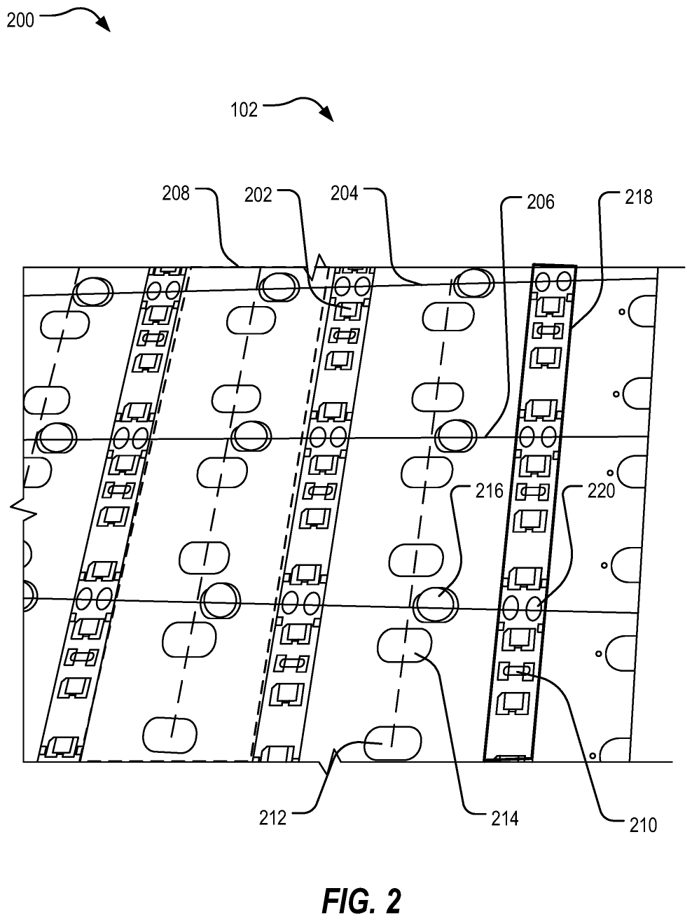

FIG. 2 illustrates an example lighting system 200 including the flexible LED sheet 102, which can be the same as or form at least a portion of the system 100 depicted in FIG. 1. The flexible LED sheet 102 depicted in FIG. 2 can be a single color flexible LED sheet 102.

In some examples, the flexible LED sheet 102 includes a plurality of repeating, discrete units (e.g., which can also be designated cuttable sections) that each include an LED 202 (or a defined set of LEDs, such as three LEDs) on a portion of the conductive rows 104. The repeatable unit 118 can be defined by a first lateral line 204, a second lateral line 206, and/or a cutting or puncturing area 208. The lateral lines 204 and 206 can run perpendicular to the conductive rows 104 and the cutting or puncturing area 208. The lateral lines 204 and/or 206 can include one or more ink lines, perforations, colored ink lines (e.g., black lines), creases, and/or other indicator of the designated lateral lines. In some instances, the lateral lines 204 and/or 206 can be cutting lines showing a designated path for trimming the flexible LED sheet 102. The lateral lines 204 and/or 206 can designate discrete units, provide dimension information, and/or be used as a visual aid for identifying the fixture attachment puncture indictors. Additionally, the lines 204 can be evenly spaced apart from each other, and a plurality of cutting or puncturing areas 208 can also evenly spaced apart from each other (e.g., with the lines 204 running perpendicular to the direction of the rows of cutting or puncturing areas 208). As such, the plurality of lines 204 can traverse the plurality of conductive rows 104 to define the repeatable unit 118 as square or rectangle repeatable unit 118. The one or more repeatable unit 118 can be substantially uniform in size and shape and can be scaled up in a repetitive pattern arrangement to include hundreds or thousands of LEDs. Additionally or alternatively, the one or more conductive paths 122 can be represented by printed ink or markings on the surface of the flexible LED sheet 102, showing were cutting and/or puncturing is to be avoided.

Furthermore, in some scenarios, the flexible LED sheet 102 includes a control chip 210 disposed on the conductive row 104. For instance, each repeatable unit 118 can have a control chip 210 designated to control components of that repeatable unit 118 (e.g., the LED 202 or the set of LEDs corresponding to the repeatable unit). By way of example, the control chip 210 can be an SMD 3528 chip (e.g., in scenarios for controlling a single LED color). One or more data paths, running parallel to the conductive rows 104, can connect the control chips 210, as discussed in greater detail below. In other words, the flexible LED sheet 102 can include a plurality of control chip 210 (e.g., a plurality of SMD 3528 chips) on the plurality of conductive rows 104 with a one-to-one correspondence to the plurality of repeatable unit 118, such that the individual repeatable units each have their own designated control chip 210.

In some instances, the flexible LED sheet 102 can include one or more fixture attachment puncture indicators providing an indication of designated areas on the flexible LED sheet 102 that can be punctured without damaging any of the functional components of the flexible LED sheet 102 (e.g., the conductive rows 104, the data path, the LEDs 202, etc.). For instance, the cutting or puncturing area 208 can include a first fixture attachment puncture indicator 212 and a second fixture attachment puncture indicator 214. Moreover, a lateral line 206 separating the cutting or puncturing areas 208 and/or the repeatable units can include a third fixture attachment puncture indicator 216. Furthermore, an LED area 218 (e.g., that includes the conductive rows 104 and the LEDs 202) can include a fourth fixture attachment puncture indicator 220 (which can also be along the lateral line 206. These fixture attachment puncture indicators can include an indication color (e.g., red) that is a different color than other portions of the surface of the flexible LED sheet 102. Additionally or alternatively, these fixture attachment puncture indicators can include one or more of an indent, perforations, or other features to assist in removing or puncturing the flexible PCB at the fixture attachment puncture indicators, and/or to provide tactile feedback for identifying the fixture attachment puncture indicators. The plurality of fixture attachment puncture indicators throughout multiple repeatable unit 118 can form a repeating pattern of fixture attachment puncture indicators.

Furthermore, in some instances, the LEDs of a conductive row 104 can be electrically connected to other conductive rows 104 of other flexible LED sheet 102 via a daisy chain configuration and/or in a series. The daisy chain configuration can wire the LEDs and/or the repeatable units together in a sequence, creating redundant loops back to the power supply. In some scenarios, portions of the flexible LED sheet 102 can be severed from a remaining portion without this severing impacting the circuitry of the remaining portion of the flexible LED sheet 102, or the ability to provide power and/or data to the remaining repeatable units of the remaining portion of the flexible LED sheet 102. In some instances, the circuitry arrangement of conductive rows 104 and/or lateral conductive paths 122 can provide a constant voltage to the LEDS during operation of the flexible LED sheet 102. In some scenarios, the power supply can provide a 200 watt power supply to the flexible LED sheet 102, which can improve energy efficiency of the system 200.

In some instances, a user of the flexible LED sheet 102 can cut the flexible LED sheet 102 to any desired shape and size. The user can cut in the designated cutting or puncturing area 208 and/or along the lines (e.g., line 204 and/or line 206). During this customization sheet cutting process, the user can cut around one or more of the fixture attachment puncture indicators to ensure that a remaining portion of the flexible LED sheet 102 includes the fixture attachment puncture indicator and material around the fixture attachment puncture indicators. This technique for selectively including the fixture attachment puncture indicators in the customized or cut flexible LED sheet 102 can provide multiple attachment areas around a border of the customized or cut flexible LED sheet 102 for mounting the customized or cut flexible LED sheet 102 to an illumination object (e.g., a sign, a display, an art installation, etc.). In some scenarios, the customized border of the flexible LED sheet 102, including the fixture attachment puncture indicators, can correspond or match with a border, shape, or size of the illumination object onto which the flexible LED sheet 102 is installed. A fixture element (e.g., a nail or a screw) can be extended through the flexible LED sheet 102 at the fixture attachment puncture indicators without causing damage to the elements of the flexible LED sheet 102. As further shown in FIG. 2, the lighting system 200 can include the flexible LED sheet 102 with an adhesive material 222 (e.g., a tape or a glue) disposed on a rear side 224 of the flexible LED sheet 102 (e.g., opposite the front side 226 including the LEDs 202).

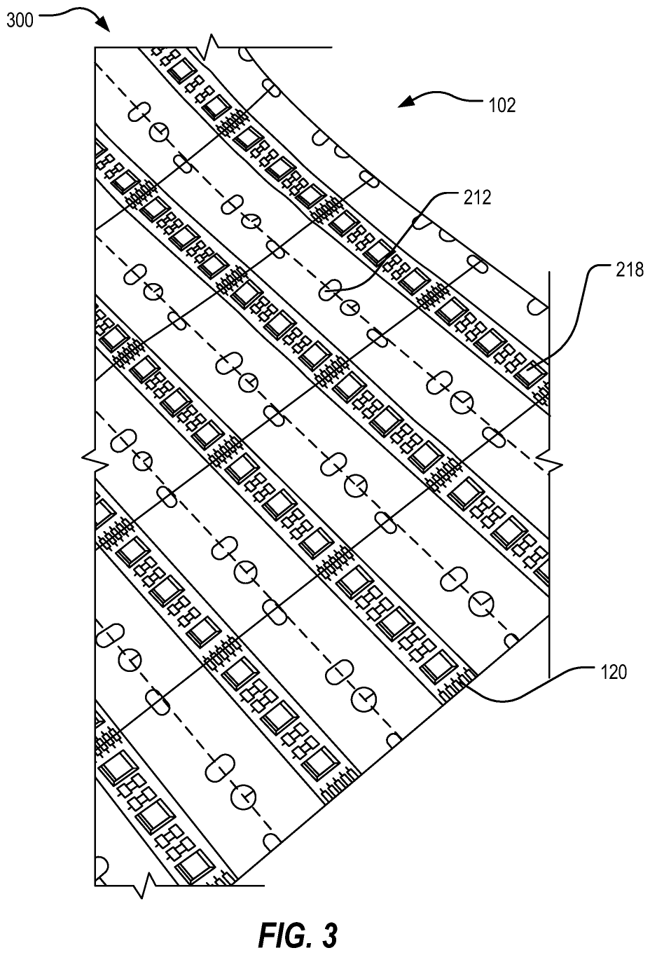

FIG. 3 illustrates an example system 300 including the flexible LED sheet 102, which can be the same as or form at least a portion of the system 100 depicted in FIG. 1. As depicted in FIG. 3, the flexible LED sheet 102 can be a red-green-blue-white (RGBW) flexible LED sheet 102.

For example, the repeatable unit 118 can each include a set of three LEDs, such as a red LED, a green LED, and a blue LED. Additionally or alternatively, the flexible LED sheet 102 can include a plurality of SMD 5050 chips and/or a plurality of CRI 95+ LED chips. For instance, an individual repeatable unit 118 can have a designated SMD 5050 chip and/or a designated CRI 95+ chip for controlling the components (e.g., the red LED, the green LED, and the blue LED) of that particular repeatable unit 118. This plurality of components can form a discrete unit of the flexible LED sheet 102, which can be repeated throughout the flexible LED sheet 102 forming the plurality of repeatable unit 118. Moreover, the plurality of components of the repeatable unit 118 can be in a line on a portion/section of the conductive row 104, in the LED area 218, and spaced apart from other repeatable units by the cutting or puncturing areas 208 on either side of the LED area 218. The cutting or puncturing areas 208 can run parallel with the LED area 218, and can be positioned between the individual repeatable units. As such, the plurality of cutting or puncturing areas 208 can alternate with the plurality of LED areas 218 containing the conductive rows 104 and the LEDs 202. Moreover, the plurality of rows of cutting or puncturing areas 208 can space the repeatable unit 118 apart from other repeatable units. The plurality of lateral lines 204, perpendicular to the conductive row 104 and the LED area 218, can also space the repeatable unit 118 apart from other repeatable units.

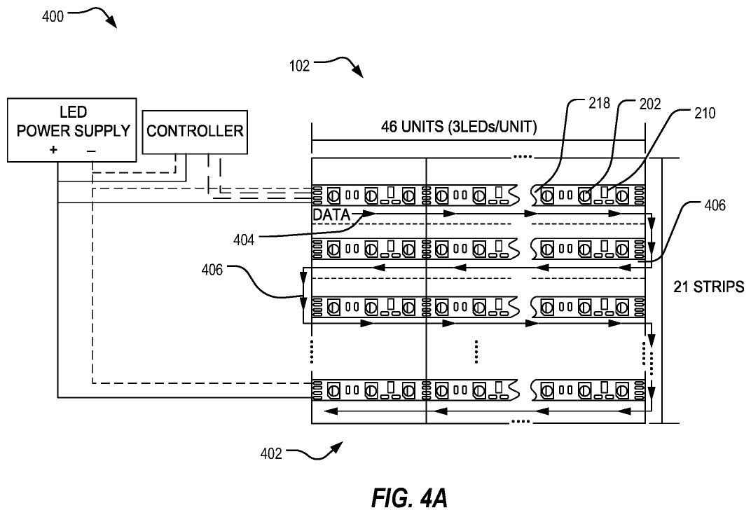

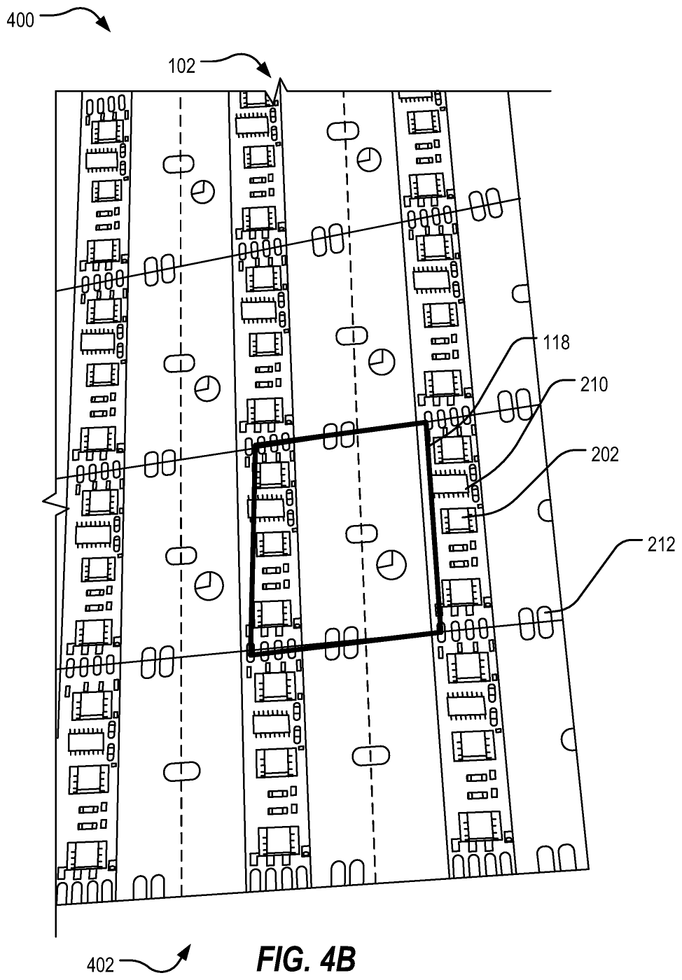

FIGS. 4A and 4B illustrate an example system 400 including the flexible LED sheet 102, which can be the same as or form at least a portion of the system 100 depicted in FIG. 1. As depicted in FIGS. 4A and 4B, the flexible LED sheet 102 can be a pixel LED sheet 402 for creating a pixel display.

In some instances, the flexible LED sheet 102 is the pixel LED sheet 402 with the individual repeatable unit 118 having a red LED, a green LED, and a blue LED. Moreover, the repeatable unit 118 can each include a SMD 4040 chip designated to the components of the particular repeatable unit 118. Additionally or alternatively, the individual repeatable unit 118 can have their own designated WS2814 chip for controlling the components of the individual repeatable units. Accordingly the chips on the flexible LED sheet 102 can control the pixel LEDS to present pictures and/or video. Additionally, the pixel LED sheet 402 can be cut to a customized shape and/or size, for instance, along the cutting or puncturing areas 208 and/or the lateral lines 204

In some examples, the flexible LED sheet 102 can include a data path 404 formed with a data line, trace, or wire embedded in the flexible PCB. In some instances, the data path 404 runs within the LED area 218, adjacent to the LED are 218, adjacent to the plurality of rows of LEDs 112 (e.g., and the conductive rows 104). The data path 404 can be a single continuous data path (e.g., omitting branches) that runs, snakes, or zig-zags back and forth along the plurality of rows of LEDs 112. For instance, the data path 404 can connect the different rows of LEDs 112 perpendicularly at alternating ends 406 of the rows of LEDs 112, forming the single, continuous data path 404. Additionally or alternatively, the data path 404 can include one or more branches running parallel to or traversing the rows of LEDs 112. As such, the data path 404 can provide control signals to the components of the repeatable unit 118 from a controller, as discussed below.

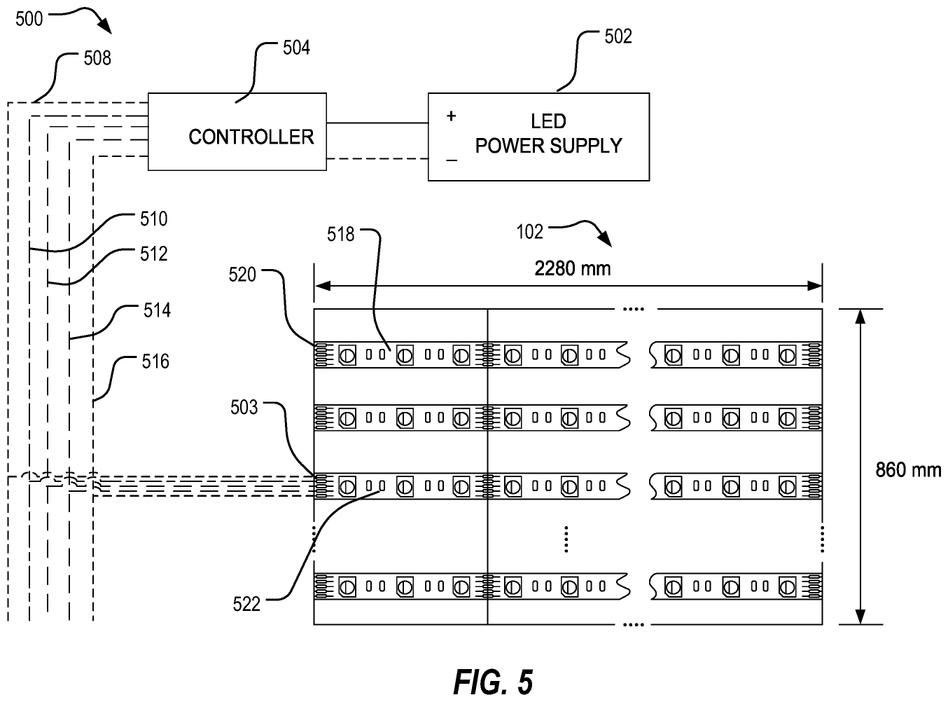

FIG. 5 illustrates an example system 500 including the flexible LED sheet 102 and a power supply 502. The system 500 depicted in FIG. 5 can be the same or form at least a portion of the system depicted in FIG. 5.

In some scenarios, as depicted in FIG. 5, the flexible LED sheet 102 can be the RGBW multi-color flexible LED sheet 102 and/or can include the plurality of SMD 5050 chips with CRI 95+ chips. The flexible LED sheet 102 can include the power connector 120 and a data connector 503, which can be integrated with and/or separate from the power connector 120. In some instances, a controller 504 can include five leads 506 communicatively coupled to the power supply 502 at five terminals at an edge or end 108 of the flexible LED sheet 102. The leads 506 of the controller 504 can include one or more power leads 508, a green LED lead 510, a blue LED lead 512, a red LED lead 514, and/or a chip lead 516. These leads 506 of the controller can connect to the data path 404 and/or the conductive rows 104 on the flexible LED sheet 102, for instance, at an end of the row at the first end 108 or the second end 110. The leads can attach to a data connection on a side row 518 of the flexible LED sheet 102, for instance, at a corner 520 of the flexible LED sheet 102. Additionally or alternatively, the data connection can be at an interior row 522, or a middle row, of the flexible LED sheet 102. The flexible LED sheet 102 can include a single data connection or multiple data connections distributed along edges of the flexible LED sheet 102. The controller 504 can also connect to and receive power from an LED power supply 502, which the controller 504 can convert to the 200 W and/or 12V DC power supply for the conductive rows 104. Turning to FIG. 5, the flexible LED sheet 102 can be a single color flexible LED sheet 102. The flexible LED sheet 102 can have two leads, a positive lead 524 and a negative lead 526, which connect to the LED power supply 502.

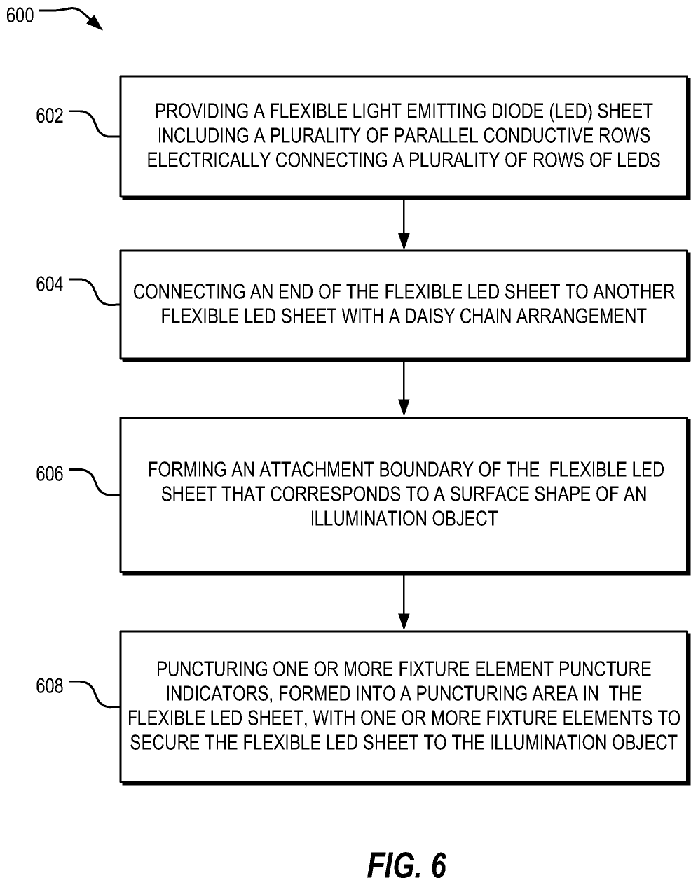

FIG. 6 illustrates an example method 600 for forming a lighting system, which can be performed by the systems 100-500 disclosed herein.

At operation 602, the method 600 can provide a flexible light emitting diode (LED) sheet including a plurality of parallel conductive rows electrically connecting a plurality of rows of LEDs. At operation 604, the method 600 can connect an end of the flexible LED sheet to another flexible sheet with a daisy chain arrangement. At operation 606, the method 600 can form an attachment boundary of the flexible ELD sheet that corresponds to a surface shape of an illumination object. At operation 608, the method 600 can puncture one or more fixture element puncture indicators, formed into the puncturing area in the flexible LED sheet, with one or more fixture elements to secure the flexible LED sheet to an illumination object.

It is to be understood that the specific order or hierarchy of steps in the method(s) depicted in FIG. 6 and throughout this disclosure are instances of example approaches and can be rearranged while remaining within the disclosed subject matter. For instance, any of the operations depicted in FIG. 6 and throughout this disclosure may be omitted, repeated, performed in parallel, performed in a different order, and/or combined with any other of the operations depicted in FIG. 6 and throughout this disclosure.

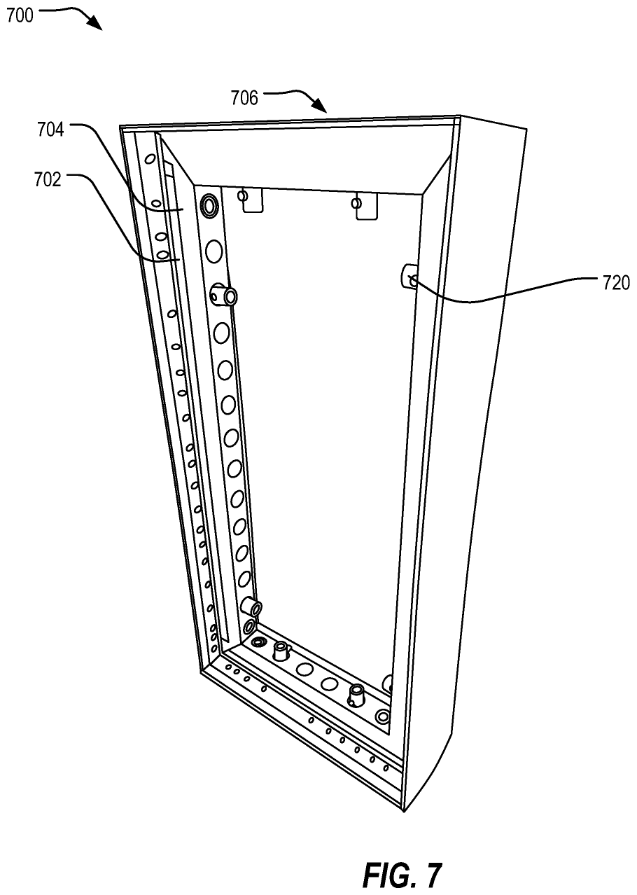

FIGS. 7-11 depict example systems 700 including one or more strips of LEDs 702 (e.g., the plurality of LEDS 106), in which the strip(s) of LEDs 702 are coupled to a substrate base structure 704. The substrate base structure 704 can form a bracket attachment to assist in installing the plurality of LEDs 106 into a backlighting frame 706 that provides a uniform and unobstructed backlighting for a material or surface extending across the backlighting frame 706. Furthermore, FIGS. 7-11 depict one or more processes or installing/attaching the LEDS 702 to a modular or non-modular frame component, thus eliminating shadowing from wiring to create a seamless backlighting and/or provide a dimension to the backlighting frame 706.

In some examples, some backlighting frames may create shadows at connection points in the frames due to the width of the frame obstructing the lighting, wiring of the lighting, and/or a front material extending across the frame (e.g., a SEG material) being too close to the backlighting frame 706. To address such, problems, the substrate base structure 704 can include one or more elongated bracket(s) 708 with one or more channels 710, which couples to an inner frame 710 to form the backlighting frame 706. Once the bracket 708 attaches to the inner frame 710, a space is created between a front surface material, such as the SEG material extending across the frame 706. Light can seamlessly pass by the backlighting frame 706 and hit the SEG material with a uniform distribution to reduce or eliminate frame edge/perimeter shadows, giving the frame a seamless light dimension.

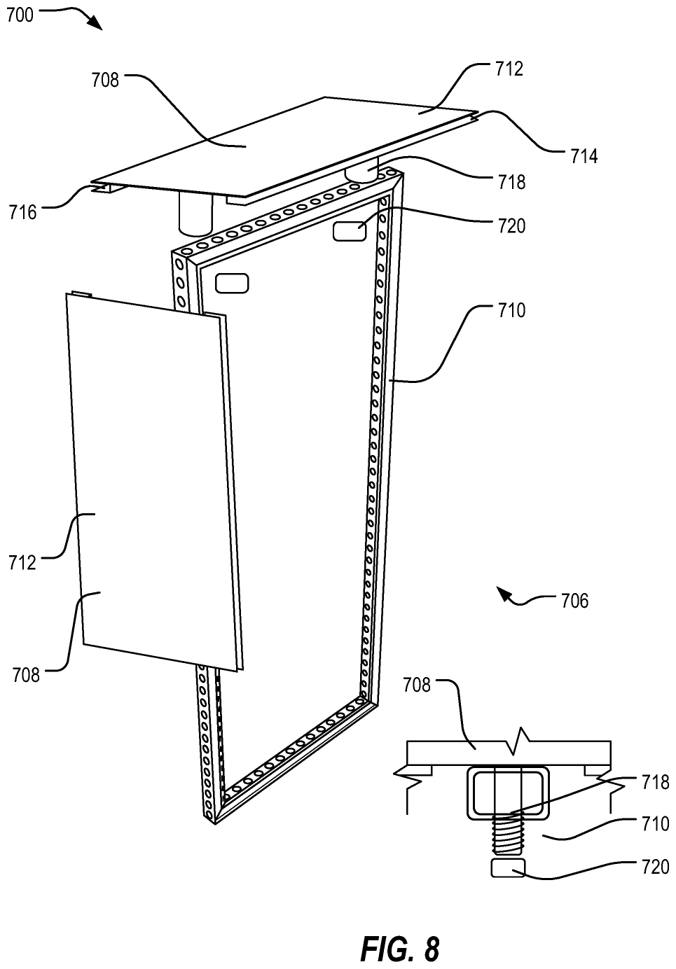

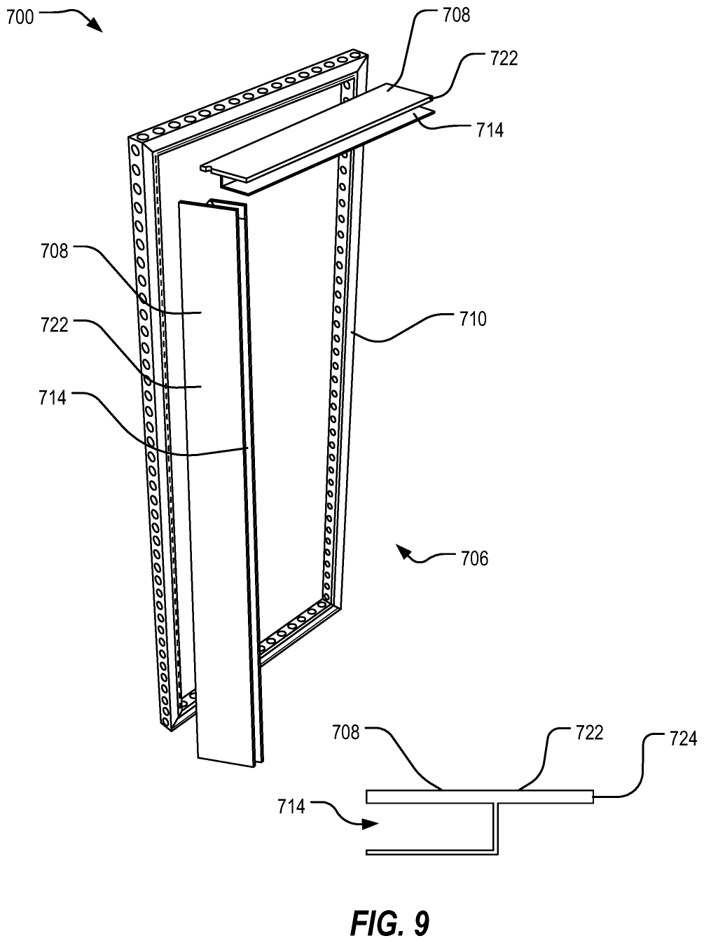

Moreover, the system 700 can be formed of modular components such as the elongated brackets 708 depicted in FIGS. 7-11. The elongated brackets 708 can include a double-sided bracket 712, as depicted in FIG. 8. The double-sided bracket 712 can include a first u-channel 714 extending from a first side and a second u-channel 716 extending from a second side, such that a material such as the SEG material can be stretched across both a front and a back of the backlighting frame 706. One or more bolts 718 can extend from a center of the double-sided bracket 712 through existing frame holes in the inner frame 710. One or more threaded caps 720 can screw onto the ends of the bolt(s) 718, securing the double-sided bracket 712 to the inner frame 710. Additionally or alternatively, the elongated brackets 708 can be single-sided brackets 722, as depicted in FIGS. 9-11. The single-sided brackets 722 can include the first u-channel 714 while omitting the second u-channel 716. For instance, the single-sided brackets 722 can abut the inner frame 710 with an inner surface, with a terminating end 724 of the single-sided brackets 722 extending from the first u-channel 714 against the inner frame 710. The terminating end 724 can be flush with or extend past a back plane of the inner frame 710. In this way, the single-sided bracket 722 can provide the terminating end first u-channel 714 extending from the front of the backlighting frame 706, and a rear of the backlighting frame 706 is formed by the surface defined by the terminating end 724 of the single-sided brackets 722 or the back plane of the inner frame 710. The inner frame 710, in some scenarios, includes a bematrix frame or an aluvision aluminum frame. In some scenarios, four double-sided brackets 712 or single-sided brackets 722 attach to the four sides of the inner frame 710, forming a rectangular bracket portion of the backlighting frame 706 surrounding the inner frame 710. In some instances, the LED strip(s) 702 can attach to and run along the inner frame 710, the inner surface(s) of the elongated bracket(s) 708, the first u-channel 714, and/or the second u-channel 716.

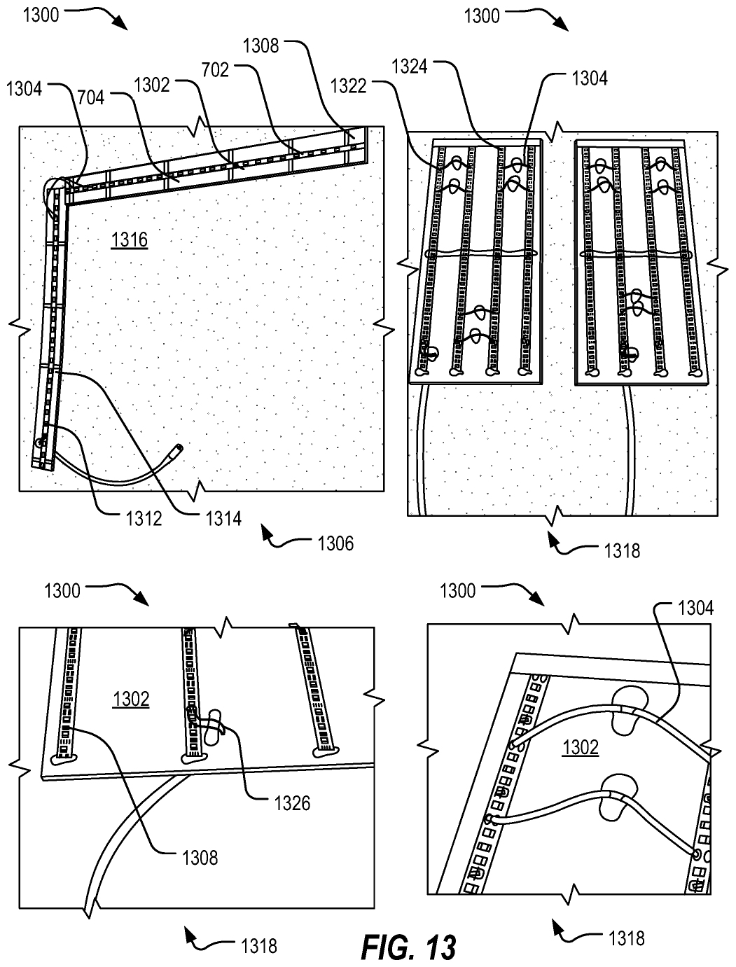

As shown in FIGS. 7-11, the backet components 708 can attach to the inner frame 710 to form the backlighting frame 706. the elongated brackets 708 can connect to form 90 degree angles, surrounding a rectangular inner frame 710. Additionally or alternatively, the elongated brackets 708 discussed herein can be attached end-to-end, such that a length or a width dimension of the substrate base structure 704, and the backlighting frame 706, is extendible in the length dimension or the width dimension. For instance, the modularity of the system 700 is depicted in FIG. 13, which shows two inner frames 710 coupled side-to-side by two top single-sided brackets 722 coupled end-to-end.

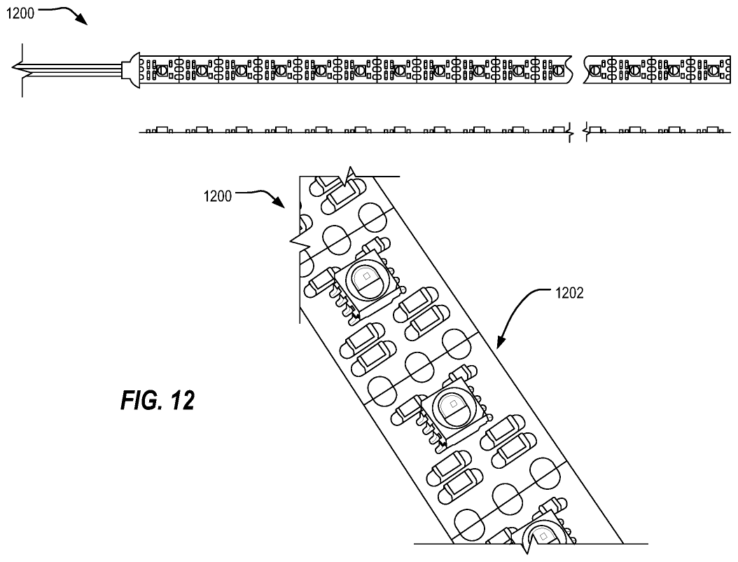

FIG. 12 depicts example systems 1200 including one more strip(s) of LEDs 702 in a 12 volt configuration 1202. For instance, the system 1200 can include a 12 Volt pixel strip with each LED individually programmed and controlled with an SK6812 IC chip inside an LED control chip. Some techniques may require a 5 Volt input. However, the techniques disclosed herein overcome this limitation with a PCB design having components configured to operate with a 12 Volt supply for the SK6812 IC chip. This 12 volt configuration can include using one or more resistors to share the voltage and reduce the 12 volt input down to 5 volts, as shown in FIG. 12. The one or more resistors can include four resistors. For instance, the one or more resistors can include three 202 resistors (e.g., 2 kΩ) and one 222 resistor (e.g., 2.2 kΩ). For instance, the three 202 resistors can be dedicated to (e.g., arranged in series with) three color LEDS (e.g., red, green, and blue), and the 222 resistor can be dedicated (e.g., arranged in series with) to half of the SK6812 IC chip generally being a white or warm white color LED, or another alternative color. When the 12 Volt input is injected into the LED strip, the 12 volt input travels and distributes to the resistors. When the voltage passes through the resistors (e.g., the three 202s and the 222) before the LED diode chip and SK6812 IC Chip, the voltage is evenly reduced. The voltage that travel through the 202 resistors travel past it and go to color section(s) (e.g., RED, GREEN or BLUE) which are the smaller sections of the LED Diode. The voltage that travels through the 222 resistor continues to the white light color section of the LED Diode, which takes up half of the LED diode. The resistors reduce the voltage to a stable and lower voltage for the SK6812 and LED chip to handle. As such, this flexible PCB can dissipate excess heat to avoid overheating or burning out the components. The PCB design disclosed herein can dissipate heat better than a 5 Volt design.

In some examples, the 12 volt configuration 1202 can be used for back lighting products, such as the backlighting frame 706 discussed above. Additionally or alternatively, the 12 volt configuration 1502 can form part of a stage lighting, a night club lighting, television lighting, film lighting, other production lighting, ambient lighting, or any other lighting application where a user benefits from full control over the programming and effects of the lighting. Moreover, a layered design of the 12 volt configuration 1502 can include a Gerber Top Overlay (GTO) front silk screen, a Gerber Top Solder (GTS) front solder mask, a Gerber Top Layer (GTL) front line, a Gerber Bottom Layer (GBL) reverse line, a Gerber Bottom Solder (GBS) reverse solder mask, and/or a Gerber Drill Rack (DRL) drilling configuration.

FIGS. 13-15 depict example systems 1300 including one or more LEDs 106 and techniques for forming the LED strip(s) 702 and/or LED arrays 116 and attaching them to a substrate surface 1302. As such, the system, 1300 can eliminate shadowing from wiring while creating a seamless strip of light preinstalled on a substrate, which can reduce installation time.

In some examples, the system 1300 includes a process/method to install the LED strip 702. The process can provide various benefits in different scenarios. By preinstalling the LED strip 702 onto a substrate surface 1302 prior to installation into its final location, multiple installation steps can be performed simultaneously and in parallel (e.g., installing the LED strip 702 to the substrate surface 1302 while the final product which will be illuminated is still being built). The substrate surface 1302 with the LED strip 702 can then be attached to the product, illumination object, or property in need of lighting. In some scenarios, the substrate surface 1302 can include aluminum, wood sintra (e.g., cell polyvinyl chloride (PVC) board), or similar material, and the LED strip 702 can be adhered to the substrate surface 1302 with hot glue or silicon over a top portion of the LED strip 702 (e.g., to couple multiple LED strips 702 together) and/or under the LED strip 702. Die bonding and/or using silicon can be used to form the LED strips 702 on to the substrate surface 1302. For instance, the strip lighting can be attached to aluminum backed/die bonded aluminum composite material (ACM) sheets. The sheets can be die bonded to provide rigidity and/or reduce flexing. Silicon can be added over the PCB to adhere it to the Di Bond/ACM sheet, overcoming previous adherence issues the industry faced. Additionally or alternatively, double-sided tape can be used to adhere the LED strip 702 to the substrate surface 1302. Furthermore adjacent LED strips 702 can be electrically coupled via a connector wire 1304 soldered to the LED strips 702. The connector wire 1304 can couple to the different LED strips 702 at soldering points inset from either end of the LED strip 702, such as solder points near a center or middle of the LED strip 702, or at least one or two connection points inset from the edge, rather than soldering points at the edges or ends of the LED strips 702, further reducing shadows around the edges of the final product from the wires.

For instance, FIG. 13 depicts a first configuration 1306 with a first LED strip 1308 adhered to a first substrate surface 1310, and a second LED strip 1312 adhered to a second substrate surface 1314. The first substrate surface 1310 and the second substrate surface 1314 can be secured to a final product surface 1316, forming a 90 degree angle relative to each other. In some examples, the system 1300 includes a second configuration 1318, with multiple LED strips 702 adhered to a single substrate surface 1302. The multiple LED strips 702 can be arranged in parallel rows with one or more connector wires 1304 electrically coupling the different LED strips 702. As shown in FIGS. 13-15, the rows of LED strips 702 can be electrically connected at connection points inset from end connection points, such that the rows of LED strips 702 are not connected at their end points. By connecting some or all of the one or more rows of LED strips 702 using inner or middle connection points instead of end connection points, the shadowing around the edges of the substrate surface 1302 are eliminated. Accordingly, multiple substrate surface 1302, each with one or more rows of LEDS, can be adhered adjacent to each other on the final location surface 1320, aligning the rows of a first substrate surface 1322 to be parallel with those of a second substrate 1324, thus forming a seamless illumination pattern.

In some examples, one or more power wires 1326 can extend through a hole in the substrate surface 1302, from a rear side of the substrate surface 1302, to couple to the power connection points on the LED strip 702. A portion of the power wire 1326 and/or the connector wire 1304 can be adhered to the substrate surface 1302 (e.g., with hot glue) on the front side including the LED strip(s) 702 and/or on the rear side of the substrate surface 1302, further minimizing shadows from the power wires 1326. Additionally or alternatively the connector wires 1304 connecting one LED strip 702 to another can also be adhered to the substrate surface 1302 (e.g., with glue or tape).

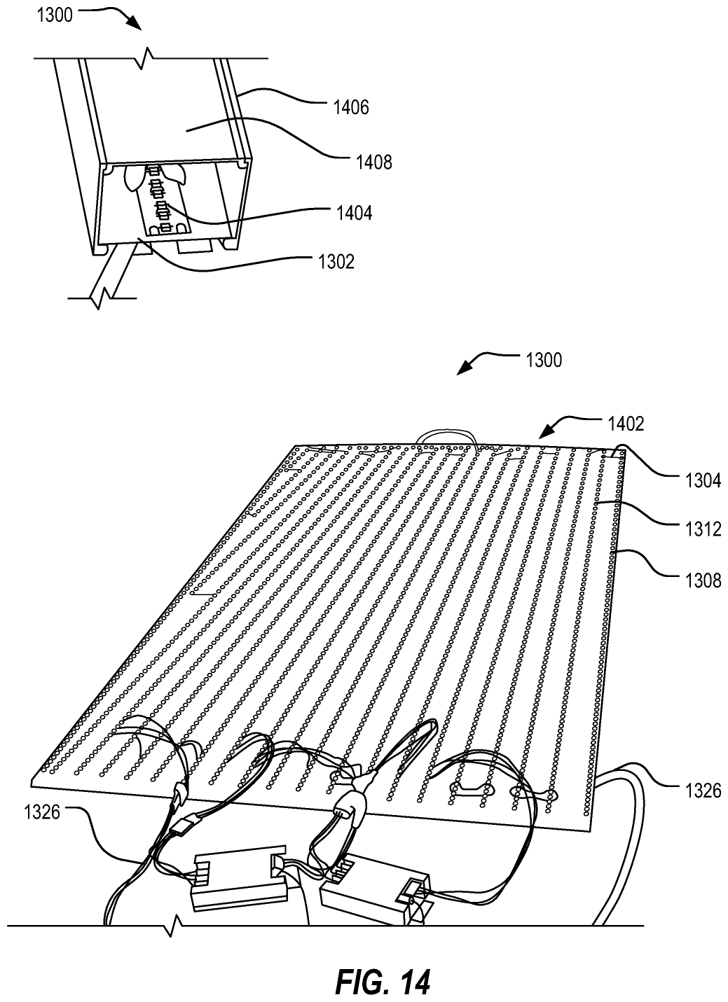

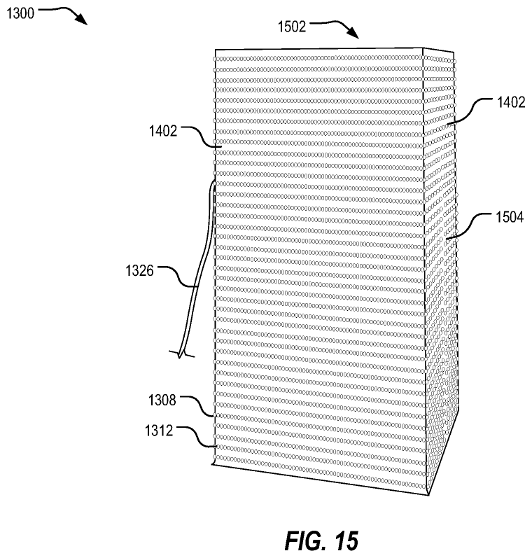

As shown in FIG. 14, the system 1300 can include an LED panel 1402 including a plurality of LED strips 702 configured as discussed herein. In some examples, The LED panel can include one or more power supplies providing power wires 1326 to the various LED strips 702 of the LED panel 1402 using the techniques discussed herein. As such, the LED panel 1402 can be manufactured with any desired dimensions or scale, including sizes multiple meters in each dimension. In some scenarios, a single LED strip 1404 can be disposed in a rectangular chassis 1406 having a translucent front cover 1408. Furthermore, as depicted in FIG. 15, a plurality of LED panels 1402 can be arranged to form a three-dimensional object 1502, such as an illumination box 1504 having four sides formed of LED panels 1402 coupling at 90 degree angles. The LED panels 1402 and/or LED strips 702 discussed herein can be arranged to illuminate a three-dimensional object 1502 having a variety of different shapes and sized objects (e.g., pyramids, cylinders, cubes, spheres, rectangular prisms, pentagons, hexagons, planes, lettering, combinations thereof, and the like).

While the presently disclosed technology has been described with reference to various implementations, it will be understood that these implementations are illustrative and that the scope of the presently disclosed technology is not limited to them. Many variations, modifications, additions, and improvements are possible. More generally, implementations in accordance with the presently disclosed technology have been described in the context of particular implementations. Functionality may be separated or combined differently in various implementations of the disclosure or described with different terminology. These and other variations, modifications, additions, and improvements may fall within the scope of the disclosure as defined in the claims that follow.

What is claimed is:

1. A lighting system comprising:
a strip of light emitting diodes (LED)s operable to produce light, the strip of LEDs including a plurality of power connection points;
a substrate surface to which the strip of LEDS are attached; and
a wire connecting the strip of LEDs to a power supply at an interior power connection point of the plurality of power connection points which is inset from an end power connection point of the plurality of power connection points.

2. The lighting system of claim 1,
further including,
an SK6812 IC chip with one or more resistors creating a 12 volt configuration for the strip of LEDs.

3. The lighting system of claim 1,
wherein,
the strip of LEDS is a first strip of LEDs, the wire is a first wire, and the interior power connection point is a first interior power connection point; and
the lighting system further includes a second strip of LED attached to the substrate surface and electrically coupled to the first strip of LEDs with a second wire connecting to a second interior power connection point on the second strip of LEDS.

4. The lighting system of claim 3,
wherein,
the second strip of LEDs is arranged perpendicularly to the first strip of LEDs.

5. The lighting system of claim 3,
wherein,
the second strip of LEDs is arranged parallel to the first strip of LEDS.

6. The lighting system of claim 3, further comprising:
wherein,
the first wire or the second wire extend through the substrate surface from behind the substrate surface.

7. The lighting system of claim 3,
wherein,
the first wire or the second wire is adhered to the substrate surface with a glue or tape.

8. The lighting system of claim 1,
wherein,
the substrate surface forms an elongated bracket coupled to an interior frame to form a backlighting frame.

9. The lighting system of claim 1,
wherein,
the strip of LEDs is one of a plurality of strips of LEDs arranged in parallel rows having a same length on the substrate surface to form an LED panel having a uniform illumination pattern.

10. The lighting system of claim 9,
wherein,
the LED panel is one of a plurality of LED panels arranged perpendicularly to form an LED cube or an LED rectangular prism.

11. A lighting system comprising:
a strip of light emitting diodes (LED)s operable to produce light, the strip of LEDs including an interior power connection point inset from an end power connection point, the interior power connection point is coupled to a power supply;
a substrate surface to which the strip of LEDS are attached forming an elongated bracket; and
an interior frame having one or more openings receiving one or more mounting bolts, extending from the elongated bracket, such that the elongated bracket couples to the interior frame to form a backlighting frame.

12. The lighting system of claim 11,
wherein,
the elongated bracket is one of a plurality of elongated brackets, having a plurality of substrate surfaces coupled together to form a rectangle with the plurality of substrate surfaces facing towards an interior of the rectangle; and
the lighting system further includes a plurality of strips of LEDs coupled to the plurality of elongated brackets to form a continuous illumination pattern around the rectangle.

13. The lighting system of claim 12,
further including,
a plurality of channels formed into the plurality of substrate surfaces for receiving the plurality of strips of LEDs; and
a fabric stretched across a perimeter edge defined by the plurality of elongated brackets, the fabric receiving backlighting from the plurality of strips of LEDs.

14. The lighting system of claim 13,
wherein,
the perimeter edge defined by the plurality of elongated brackets is spaced a distance apart from the plurality of strips of LEDs such that an illumination pattern from the plurality of strips of LEDs reaching the perimeter edge causes the backlighting of the fabric to omit edge shadows.

15. The lighting system of claim 13,
wherein,
the elongated bracket is a double-sided bracket with the perimeter edge being a front perimeter edge; and
the lighting system further includes a rear perimeter edge defined by the plurality of elongated brackets, such that the one or more mounting bolts extend from a center portion of the elongated bracket spaced between the front perimeter edge and a rear perimeter edge.

16. The lighting system of claim 11,
wherein,
the interior frame is a first interior rectangular frame; and
the backlighting frame includes a second interior rectangular frame arranged adjacent to the first interior rectangular frame.

17. The lighting system of claim 16,
wherein,
the elongated bracket is one of a plurality of elongated brackets including:
a first top bracket extending along a first top portion of the first interior rectangular frame; and
a second top bracket, arranged end-to-end with the first top bracket, extending along a second top portion of the second interior rectangular frame.

18. A method of forming a lighting system, the method comprising:
attaching a strip of light emitting diodes (LED)s, operable to produce light, to a substrate surface, the strip of LEDs including one or more interior power connection points and one or more end power connection points; and
electrically coupling a wire to at least one of the one or more interior power connection points to provide power to the strip of LEDS such that an illumination pattern of the strip of LEDS omits wire shadows or perimeter edge shadows.

19. The method of claim 18,
wherein,
the strip of light emitting diodes is one of a plurality of LEDs coupled to one or more substrate surfaces; and
the method further includes coupling the one or more substrate surfaces to a base structure to form an illumination structure.

20. The method of claim 19,
wherein,
the base structure includes a plurality of panels, and the illumination structure is a rectangular prism or cube formed by the plurality of panels; or
the base structure includes one more interior frames with openings for receiving a plurality of bolts extending from the one or more substrate surfaces.
